(19) United States
(12) Patent Application Publication
(10) Pub. No.: US 2025/0140652 A1
(43) Pub. Date: May 1, 2025

(54) SEMICONDUCTOR MODULE

(71) Applicant: SHINDENGEN ELECTRIC MANUFACTURING CO., LTD., Tokyo (JP)

(72) Inventors: Yuji MORINAGA, Saitama (JP); Junya YUGUCHI, Saitama (JP)

(21) Appl. No.: 18/929,620

(22) Filed: Oct. 29, 2024

(30) Foreign Application Priority Data
Oct. 31, 2023 (JP) 2023-187047

(51) Int. Cl. H01L 23/495; H01L 23/06

(52) U.S. Cl. CPC H01L 23/4952; H01L 23/06; H01L 23/49575

(57) ABSTRACT

Provided is a semiconductor module that can also reduce difficulty in mounting while reducing a parasitic inductance. The semiconductor module that includes: a plurality of semiconductor chips arranged inside a mold resin M; and a plurality of terminals (first power source terminal, one second power source terminal, the other second power source terminal, first intermediate point terminal, and second intermediate point terminal) each having an inner lead portion that is positioned inside the mold resin and having an outer lead portion that is positioned outside the mold resin. The outer lead portion of the first power source terminal has a distal end branched structure where a distal end of the terminal at the outer lead portion is branched in plurals.

### CROSS REFERENCE TO RELATED APPLICATIONS

This application claims priority to Japanese Patent Application No. 2023-187047, filed on Oct. 31, 2023, which is expressly incorporated herein by reference in its entirety.

### TECHNICAL FIELD

The present invention relates to a semiconductor module.

### BACKGROUND ART

Conventionally, there has been popularly adopted a configuration where a bridge circuit is formed of a plurality of semiconductor chips. In the bridge circuit, there may be a case where an electric power loss or ringing occurs attributed a parasitic inductance in a circuit. Particularly, in a case where a wide band gap semiconductor is used as a semiconductor chip, such a semiconductor exhibits a high through rate and a high operation frequency, an electric power loss or ringing is likely to be generated due to a parasitic inductance in a circuit. The magnitude of the parasitic inductance largely depends on a wiring path length (also referred to as a current path length) and hence, the modularization of a circuit is also considered for reducing the parasitic inductance (see patent literature 1, for example).

A semiconductor device 900 that is disclosed in patent literature 1, as illustrated in FIG. 9, is constituted of first to fourth semiconductor chips Q1 to Q4, a first power source terminal 911, a second power source terminal 912, a first intermediate point terminal 921 and a second intermediate point terminal 922, and a bridge circuit is formed in the semiconductor device 900.

### CITATION LIST

### Patent Literature

PTL 1: PCT No. 2020/241239

### SUMMARY OF INVENTION

### Technical Problem

However, a parasitic inductance can be reduced by making wiring short and bold. However, the simple modularization of the semiconductor module having the current path described above, is insufficient for acquiring an effect of reducing a parasitic inductance and this has been considered as a drawback. Further, in a case where a width of a terminal is simply widened, this time, a thermal capacity of the terminal is increased due to the increase of the width of the terminal and hence, it is considered that difficulty in mounting a semiconductor module using a conductive joining material (for example, a solder) becomes high.

The present invention has been made in view of such drawbacks, and it is an object of the present invention to provide a semiconductor module that can also reduce difficulty of mounting while reducing a parasitic inductance.

### Solution to Problem

A semiconductor module according to the present invention is a semiconductor module that includes: a plurality of semiconductor chips arranged inside a mold resin; and a plurality of terminals each having an inner lead portion that is positioned inside the mold resin and having an outer lead portion that is positioned outside the mold resin, wherein a width of at least one terminal out of the plurality of terminals is set such that the terminal has a desired inductance, and the terminal has a distal end branched structure where a distal end of the terminal at the outer lead portion is branched in plurals.

### Advantageous Effects of the Invention

In the semiconductor module of the present invention, the width of at least one terminal out of the plurality of terminals is set so as to have a desired inductance, and the terminal has the distal end branched structure where the distal end of the terminal at the outer lead portion is branched in plurals. With such a configuration, according to the semiconductor module of the present invention, with respect to at least one terminal out of the plurality of terminals, even in a case where a width of the terminal is increased to a terminal width at which a parasitic inductance is not largely increased from the inner lead portion to the outer lead portion (the width having a desired inductance), the increase of the width of the distal end of the terminal can be suppressed because of the distal end branched structure and hence, a heat capacity of a mounting portion can be reduced thus enabling the lowering the difficulty in mounting. Accordingly, the semiconductor module according to the present invention becomes a semiconductor module that can also lower difficulty in mounting while reducing a parasitic inductance.

### BRIEF DESCRIPTION OF DRAWINGS

FIG. 1 is a plan view of the internal configuration of a semiconductor module 1 according to an embodiment 1.

FIG. 2A and FIG. 2B are front views and a back view of the semiconductor module 1 according to the embodiment 1. FIG. 2A is a front view of the semiconductor module 1 (a view as viewed from a side of a first power source terminal 51, one second power source terminal 52 and the other second power source terminal 53). FIG. 2B is a back view of the semiconductor module 1 (a view as viewed from a first intermediate point terminal 61 and a second intermediate point terminal 62). In FIG. 2A and FIG. 2B, symbols are given to only terminals on a side close to a point of view in a drawing. The same goes for FIG. 6A and FIG. 6B and FIG. 8A and FIG. 8B described later.

FIG. 3 is a plan view of the internal configuration of a semiconductor module 1A prepared for performing a comparison with the semiconductor module 1 according to the embodiment 1.

FIG. 4 is a graph illustrating the relationship between a frequency and an inductance with respect to the semiconductor module 1 according to the embodiment 1 and the semiconductor module 1A. FIG. 4 is a graph illustrating a result of inductance simulation of a wiring path when both a first semiconductor chip Q1 and a fourth semiconductor chip Q4 are turned on.

FIG. 5 is a plan view of the internal configuration of a semiconductor module 2 according to an embodiment 2.

FIG. 6A and FIG. 6B are front views and a back view of the semiconductor module 2 according to the embodiment 2. FIG. 6A is a front view of the semiconductor module 2 (a view as viewed from a side of a first power source terminal 51a and a second power source terminal 52a). FIG. 6B is a back view of the semiconductor module 2 (a view as viewed from a side of a first intermediate point terminal 61a and a second intermediate point terminal 62a).

FIG. 7 is a plan view of the internal configuration of a semiconductor module 3 according to an embodiment 3.

FIG. 8A and FIG. 8B are front views and a back view of the semiconductor module 3 according to the embodiment 3. FIG. 8A is a front of the semiconductor module 3 (a view as viewed from a side of a first power source terminal 51b and a second power source terminal 52b). FIG. 8B is a back view of the semiconductor module 3 (a view as viewed from a side of an intermediate point terminal 61b).

FIG. 9 is a plan view of the internal configuration of a semiconductor device 900 described in patent literature 1.

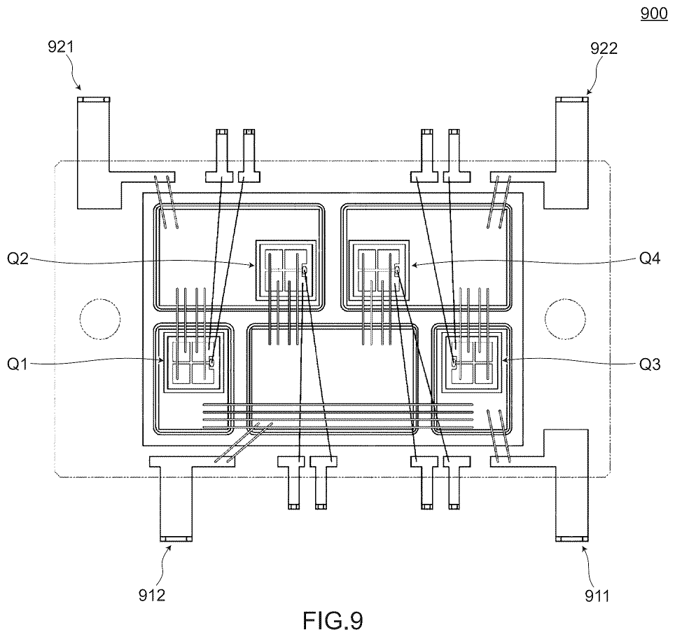

### MODE FOR CARRYING OUT THE INVENTION

Hereinafter, semiconductor modules according to the present invention are described with reference to respective embodiments illustrated in the drawings. In the respective embodiments described hereinafter, with respect to each constitutional element having substantially the same function is indicated using the same symbol in all embodiments, and the repeated description of the constitutional element is omitted even in a case where the constitutional elements slightly differ from each other in shape or the like. The respective embodiments described hereinafter are not intended to restrict the inventions called for in Claims. Further, it is not always the case that all of the various constitutional elements described in the respective embodiments and combinations of these constitutional elements are indispensable as a means to solve the problems of the present invention.

### Embodiment 1

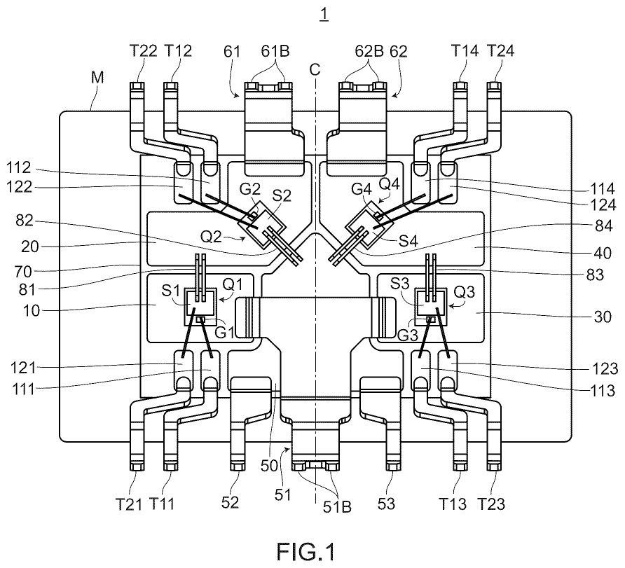

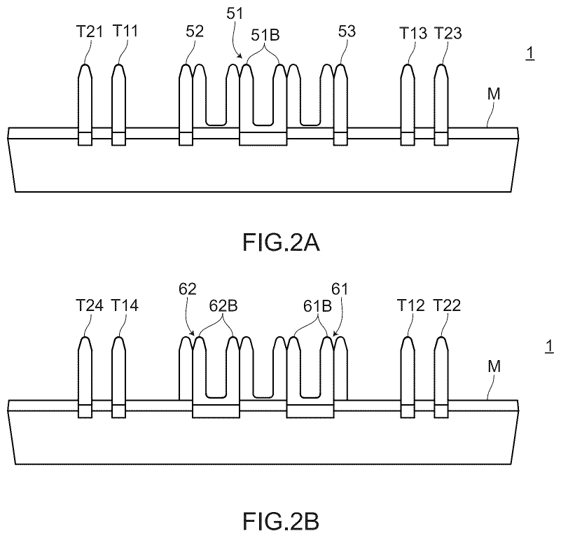

Hereinafter, the internal constitutional configuration of a semiconductor module 1 according to an embodiment 1 is described with reference to FIG. 1 and FIG. 2A and FIG. 2B. As illustrated in FIG. 1, the semiconductor module 1 according to the embodiment 1 includes a plurality of semiconductor chips disposed in a mold resin M, and a plurality of terminals.

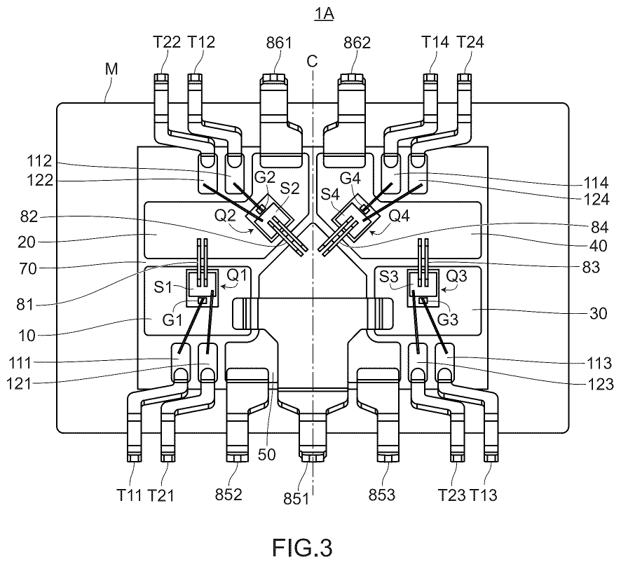

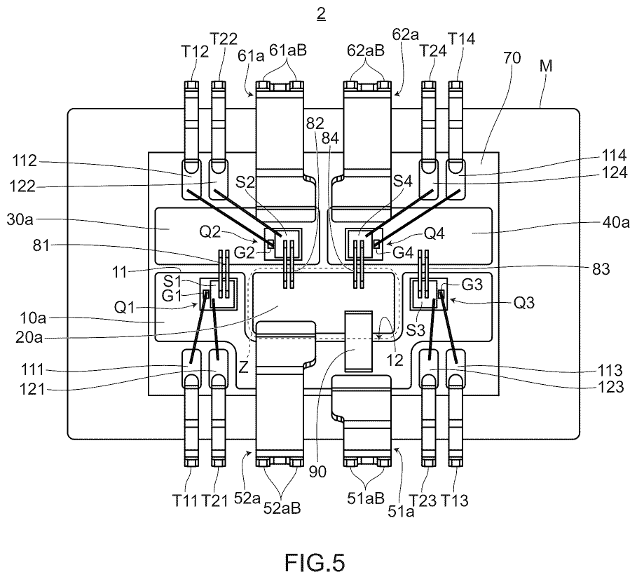

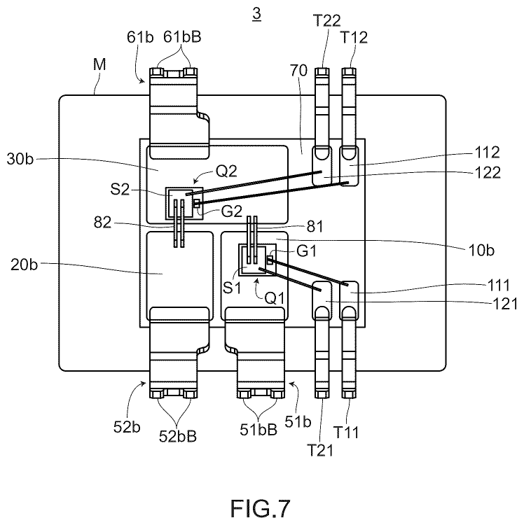

Although the semiconductor module 1 is resin-shielded by the mold resin M, FIG. 1 illustrates the internal configuration of the semiconductor module 1 and hence, only an outer edge is displayed with respect to the mold resin M. The same goes for FIG. 3, FIG. 5 and FIG. 7 described later.

The semiconductor module 1 includes four semiconductor chips (first to fourth semiconductor chips Q1 to Q4) as the plurality of semiconductor chips, at the same time, further includes a first power source terminal 51, a second power source terminal, a first intermediate point terminal 61 and a second intermediate point terminal 62 as the plurality of terminals. To further describe the configuration, the semiconductor module 1 includes one second power source terminal 52 and the other second power source terminal 53 as the second power source terminal. In this manner, the semiconductor module 1 is a semiconductor module in which a bridge circuit is formed. The first power source terminal 51, the second power source terminal (one second power source terminal 52 and the other second power source terminal 53), the first intermediate point terminal 61 and the second intermediate point terminal 62 that are the plurality of terminals are disposed such that respective inner lead portions of the plurality of terminals are positioned inside the mold resin M, and the respective outer lead portions of the plurality of terminals are positioned outside the mold resin M.

Further, the semiconductor module 1 includes, besides above-mentioned constitutional elements, first to fifth wiring pattern 10 to 50, a substrate 70, first to fourth connecting members 81 to 84, first to fourth control-use connecting members (symbols not illustrated in the drawing), first to fourth detection-use connecting members (symbols not illustrate in the drawing), first to fourth control-use wiring patterns 111 to 114, first to fourth detection-use wiring patterns 121 to 124, first to fourth control-use terminals T11 to T14, and first to fourth detection-use terminals T21 to T24. The semiconductor module 1 may further include constitutional elements other than above-mentioned constitutional elements. In the semiconductor module 1, the bridge circuit is formed in such a manner that the first semiconductor chip Q1 and the third semiconductor chip Q3 are disposed on a high side and the second semiconductor chip Q2 and the fourth semiconductor chip Q4 are disposed on a low side.

The first power source terminal 51, one second power source terminal 52 and the other second power source terminal 53 function as input power source terminals, and the first intermediate point terminal 61 and the second intermediate point terminal 62 function as output power source terminals. In such a bridge circuit, an operation of turning on both the first semiconductor chip Q1 and the fourth semiconductor chip Q4 and an operation of turning on both the third semiconductor chip Q3 and the second semiconductor chip Q2 are alternately repeated. The bridge circuit is formed on the substrate 70.

When both the first semiconductor chip Q1 and the fourth semiconductor chip Q4 are turned on, both the third semiconductor chip Q3 and the second semiconductor chip Q2 are turned off. On the other hand, when the both the third semiconductor chip Q3 and the second semiconductor chip Q2 are turned on, the first semiconductor chip Q1 and the fourth semiconductor chip Q4 are turned off. In this specification, a state where the semiconductor chips are turned off is omitted.

A maximum width of an inner lead portion and a maximum width of an outer lead portion of the first power source terminal 51 are larger than a maximum width of an inner lead portion and a maximum width of an outer lead portion of one second power source terminal 52 and a maximum width of an inner lead portion and a maximum width of an outer lead portion of the other second power source terminal 53. Further, a width of the first power source terminal 51 on a boundary between the inner lead portion and the outer lead portion is larger than a width of a boundary between the inner lead portion and the outer lead portion of one second power source terminal 52 and a width of a boundary between the inner lead portion and the outer lead portion of the other second power source terminal 53.

In the semiconductor module 1, a width of at least one terminal out of a plurality of the terminals is set to have a desired inductance, and the outer lead portion has a distal end branched structure where a terminal end of the outer lead portion is branched in plurals. In this specification, expression “a width set to have a desired inductance” means that a minimum width of a portion that does not have the distal end branched structure becomes a width two times or more larger than a maximum width of the branched terminal distal end. To describe a specific example with respect to the expression “a width set to have a desired inductance”, for example, in a case where a wiring length from a distal end of a distal end branched structure (distal end bifurcated structure described later) of the first power source terminal 51 to a boundary between the inner lead portion and the outer lead portion is 6.5 mm, the terminal width (the minimum width of a portion that does not have a distal end branched structure) becomes 3.5 mm, and an inductance becomes 2 nH. It is needless to say that the present invention is not limited to such numerical values described above.

Further, in this specification, the expression “the terminal width” means the largest length out of the lengths of the terminal and out of the lengths along the direction orthogonal to the direction along which a current flows and parallel to a surface of the terminal. In a semiconductor module such the semiconductor module 1, it is often the case that a terminal width corresponds to a width of a surface that is viewed as viewed in a plan. Further, in this specification, the expression “distal end branched structure where a distal end is branched in plural” means not only the structure where only the terminal distal end is branched in plural, but also the structure where the terminal is breached in plural from a proximal end portion to the distal end of the terminal. In the semiconductor module 1, out of the first power source terminal 51, one second power source terminal 52 and the other second power source terminal 53, only the outer lead portion of the first power source terminal 51 has the distal end branched structure 51B (see FIG. 2A).

In the first power source terminal 51 and the second power source terminal (one second power source terminal 52 and the other second power source terminal 53), a maximum width of the inner lead portion is set larger than a maximum width of the outer lead portion. Further, out of the first power source terminal 51 and the second power source terminal, at least one terminal (the first power source terminal 51 in the embodiment 1) has the distal end branched structure 51B outside the mold resin M.

In this specification, the expression “has a distal end branched structure outside a mold resin” means that the branching of the terminal starts outside the mold resin (a branching point of the terminal existing outside the mold resin).

Both the outer lead portions of the first intermediate point terminal 61 and the second intermediate point terminal 62 each have a distal end branched structure 61B, 62B (see also FIG. 2B). Also in both the first intermediate point terminal 61 and the second intermediate point terminal 62, a maximum width of the inner lead portion is set larger than a maximum width of the outer lead portion. Further, the first intermediate point terminal 61 and the second intermediate point terminal 62 each have the distal end branched structure 61B, 62B outside the mold resin M.

In the semiconductor module 1, the respective distal end branched structure 51B, 61B, 62B of the first power source terminal 51, the first intermediate point terminal 61 and the second intermediate point terminal 62 are formed of a distal end bifurcated structure where the distal end of the terminal is branched in two. A maximum width of the inner lead portion of each terminal is two times or more as large as a terminal width of a branched portion in the distal end bifurcated structure.

In the semiconductor module 1, none of the first to fourth control-use terminals T11 to T1 and the first to fourth detection terminals T21 to T24 have the distal end branched structure.

In the semiconductor module 1, as illustrated in FIG. 1, the first semiconductor chip Q1 and the third semiconductor chip Q3 are arranged in line symmetry with respect to a center line C, and the second semiconductor chip Q2 and the fourth semiconductor chip Q4 are also arranged in line symmetry with respect to the center line C. Further, such a line symmetry relationship with respect to the center line C also exists between the first wiring pattern 10 and the third wiring pattern 30, between the second wiring pattern 20 and the fourth wiring pattern 40, the first intermediate point terminal 61 and the second intermediate point terminal point 62, between one second power source terminal 52 and the other second power source terminal 53. Further, the fifth wiring pattern 50 and the first power source terminal 51 are respectively formed in line symmetry with respect the center line C.

In the semiconductor module 1, the first intermediate point terminal 61 and the second intermediate point terminal 62 are disposed adjacently to each other on one side of the semiconductor module 1. Further, the first power source terminal 51, one second power source terminal 52 and the other second power source terminal 53 are disposed adjacently to each other on the other side of the semiconductor module 1. The first power source terminal 51 is disposed in a space above the fifth wiring pattern 50 in a non-contact state, and connects the first wiring pattern 10 and the third wiring pattern 30 to each other.

In the semiconductor module 1, the first to fourth semiconductor chips Q1 to Q4 are formed of the first semiconductor chip Q1, the second semiconductor chip Q2, the third semiconductor chip Q3 and the fourth semiconductor chip Q4. Further, the first to fifth wiring patterns 10 to 50 are formed of the first wiring pattern 10, the second wiring pattern 20, the third wiring pattern 30, the fourth wiring pattern 40 and the fifth wiring pattern 50. In the description made hereinafter, when the first to fourth semiconductor chips Q1 to Q4 are collectively described, there may be a case where the expression “the first” and the like is omitted, and the first to fourth semiconductor chips Q1 to Q4 are expressed as “semiconductor chips Q1 to Q4”. Further, in the description made hereinafter, when the first to fifth wiring patterns 10 to 50 are collectively described, there may be a case where the expression “the first” and the like are omitted, and the first to fifth wiring patterns 10 to 50 are expressed as “wiring patterns 10 to 50”.

In the semiconductor module 1, the description is made by assuming that the semiconductor chips Q1 to Q4 are each formed of a metal oxide semiconductor field effect transistor (MOSFET) and that has a rectangular shape as viewed in a plan view. Further, in the semiconductor module 1, assume that the wiring patterns 10 to 50 are formed on the substrate 70 formed of a direct copper bonding (DCB) substrate that is a ceramic substrate where metal (copper) is directly bonded to a base made of ceramic (alumina, aluminum nitride, silicon nitride or the like).

The substrate used for the semiconductor module according to the present invention is not limited to the DCB substrate, and other ceramic substrates such as an active metal brazing (AMB) substrate, a metal base substrate such as a copper base substrate or an aluminum base substrate, and the like can be also used. As metal bonded to the ceramic substrate, besides copper, other metals (aluminum, for example) can be also used.

The semiconductor chips Q1 to Q4 each have a source electrode S, a drain electrode, and a gate electrode G. In a case where a vertical transistor chip (a vertical transistor chip such as a MOSFET formed using Si or SiC) is used as the semiconductor chips Q1 to Q4, the drain electrode is configured to be formed on surfaces of the semiconductor chips Q1 to Q4 on a wiring pattern 10 to 40 side (back surfaces of the semiconductor chips Q1 to Q4). With respect to the semiconductor module 1, a case is exemplified where a vertical transistor chip is used as the semiconductor chips Q1 to Q4. Accordingly, the drain electrode that is formed on the wiring pattern 10 to 40 side cannot be visually recognized and hence, symbol that indicates the drain electrode is not illustrated in the drawing. On the other hand, the gate electrode G is formed on surfaces of the semiconductor chips Q1 to Q4 on a source electrode S side.

Further, the semiconductor chips Q1 to Q4 can be suitably changed within a scope that the gist of the present invention is not changed. For example, as the semiconductor chips Q1 to Q4, a horizontal transistor chip may be used, for example. As the horizontal transistor chip, a GaN-HEMT made of a GaN on Si material, a compound semiconductor transistor made of Ga₂O₃ on Si material and the like can be named. In case of the horizontal transistor chip, it is preferable that, besides the drain electrode, a plurality of gate electrodes G and a plurality of source electrodes S be formed on a surface of the semiconductor chip. Further, the semiconductor chips Q1 to Q4 are not limited to a transistor chip, and a modified configuration where the transistor chip is suitably replaced with a diode chip may be adopted corresponding to a circuit application. By adopting such a modified configuration, it is possible to apply the present invention to a totem-pole-type bridgeless PFC circuit and the like when desired.

In the semiconductor module 1, a region of the second wiring pattern 20 to which the first intermediate point terminal 61 is connected and a region of the fourth wiring pattern 40 to which the second intermediate point terminal 62 is connected are disposed adjacently to each other.

In the semiconductor module 1, the first wiring pattern 10 and the third wiring pattern 30 are disposed adjacently to both sides of the fifth wiring pattern 50 (a second portion described later). Further, one second power source terminal 52 and the other second power source terminal 53 are disposed on both sides of the fifth wiring pattern 50 (a first portion described later). The first power source terminal 51 has a substantially T shape as viewed in a plan view.

Although the illustration and the description are omitted, the semiconductor module 1 may include a first decoupling capacitor that is disposed in the vicinity of the first semiconductor chip Q1 and the second semiconductor chip Q2 and is connected to the first wiring pattern 10 and the fifth wiring pattern 50 to each other. Further, the semiconductor module 1 may include a second decoupling capacitor that is disposed in the vicinity of the third semiconductor chip Q3 and the fourth semiconductor chip Q4, and is connected to the third wiring pattern 30 and the fifth wiring pattern 50. The respective decoupling capacitors may have a function of avoiding fluctuation of a power source voltage and a function of removing various types of noises.

In the semiconductor module 1, the fifth wiring pattern 50 is disposed at a center portion as viewed in a plan view. The fifth wiring pattern 50 has a first portion that is positioned on the other side of the semiconductor module 1, and one second power source terminal 52 and the other second power source terminal 53 are connected. Further, the fifth wiring pattern 50 has a second portion that is positioned between the first wiring pattern 10 and the third wiring pattern 30. Further, the fifth wiring pattern 50 has a third portion that protrudes toward one side of the semiconductor module 1 from a second portion. A tapered protruding portion having a first oblique side and a second oblique side is formed on the third portion.

An angle θ made by the first oblique side and the second oblique side of the protruding portion is not particularly limited. However, in the semiconductor module 1, the angle θ is indicated as 90 degrees. Accordingly, an oblique side of the second wiring pattern 20 that corresponds to the first oblique side and an oblique side of the fourth wiring pattern 40 that corresponds to the second oblique side respectively make an angle of 45 degrees.

In the semiconductor module 1, the first semiconductor chip Q1 includes a first gate electrode G1, a first source electrode S1 and a first drain electrode. The first gate electrode G1 is connected to the first control-use terminal T11 via a first control-use connecting member (symbol not illustrated) made of an aluminum wire or the like and the first control-use wiring pattern 111. The first source electrode S1 is connected to the first detection-use terminal T21 via a first detection-use connecting member (symbol not illustrated) made of an aluminum wire or the like and the first detection-use wiring pattern 121. Further, the first source electrode S1 is connected to the second wiring pattern 20 via the first connecting member 81 made of an aluminum wire or the like. The first drain electrode is connected to the first wiring pattern 10.

Further, In the semiconductor module 1, the second semiconductor chip Q2 includes a second gate electrode G2, a second source electrode S2 and a second drain electrode. The second gate electrode G2 is connected to the second control-use terminal T12 via a second control-use connecting member (symbol not illustrated) made of an aluminum wire or the like and the second control-use wiring pattern 112. The second source electrode S2 is connected to the second detection-use terminal T22 via a second detection-use connecting member (symbol not illustrated) made of an aluminum wire or the like and the second detection-use wiring pattern 122. Further, the second source electrode S2 is connected to the fifth wiring pattern 50 via the second connecting member 82 made of an aluminum wire or the like. The second drain electrode is connected to the second wiring pattern 20.

Further, In the semiconductor module 1, the third semiconductor chip Q3 includes a third gate electrode G3, a third source electrode S3 and a third drain electrode. The third gate electrode G3 is connected to the third control-use terminal T13 via a third control-use connecting member (symbol not illustrated) made of an aluminum wire or the like and the third control-use wiring pattern 113. The third source electrode S3 is connected to the third detection-use terminal T23 via a third detection-use connecting member (symbol not illustrated) made of an aluminum wire or the like and the third detection-use wiring pattern 123. Further, the third source electrode S3 is connected to the fourth wiring pattern 40 via the third connecting member 83 made of an aluminum wire or the like. The third drain electrode is connected to the third wiring pattern 30.

Further, In the semiconductor module 1, the fourth semiconductor chip Q4 includes a fourth gate electrode G4, a fourth source electrode S4 and a fourth drain electrode. The fourth gate electrode G4 is connected to the fourth control-use terminal T14 via a fourth control-use connecting member (symbol not illustrated) made of an aluminum wire or the like and the fourth control-use wiring pattern 114. The fourth source electrode S4 is connected to the fourth detection-use terminal T24 via a fourth detection-use connecting member (symbol not illustrated) made of an aluminum wire or the like and the fourth detection-use wiring pattern 124. Further, the fourth source electrode S4 is connected to the fifth wiring pattern 50 via the fourth connecting member 84 made of an aluminum wire or the like. The fourth drain electrode is connected to the fourth wiring pattern 40.

In the semiconductor module 1, the second semiconductor chip Q2 is disposed such that one side out of a plurality of sides of the second semiconductor chip Q2 extends along the first oblique side of the fifth wiring pattern 50. Further, the fourth semiconductor chip Q4 is disposed such that one side out of the plurality of sides of the fourth semiconductor chip Q4 extends along the second oblique side of the fifth wiring pattern 50.

In the semiconductor module 1, with respect to the first power source terminal 51, one second power source terminal 52, the other second power source terminal 53, the first intermediate point terminal 61 and the second intermediate point terminal 62, a width of the inner lead portion of each terminal is set larger than a width of an outer lead portion of each terminal.

Next, the first power source terminal 51, one and the other second power source terminals 52, 53 and the first and the second intermediate point terminals 61, 62 are described. The first power source terminal 51 and one and the other second power source terminals 52, 53 are terminals that supply electricity to the bridge circuit. As viewed from the flow of a current, assume that the first power source terminal 51 is a terminal on an input side of a current, and one and the other second power source terminals 52, 53 are terminals on an output side of a current.

The first intermediate point terminal 61 and the second intermediate point terminal 62 are terminals to which a load not illustrated in the drawing is connected. The first intermediate point terminal 61 is connected to the second wiring pattern 20, and the second intermediate point terminal 62 is connected to the fourth wiring pattern 40. Then, between a case where both the first semiconductor chip Q1 and the fourth semiconductor chip Q4 are turned on and a case where the third semiconductor chip Q3 and the second semiconductor chip Q2 are turned on, the direction of a current that flows between the first intermediate point terminal 61 and the second intermediate point terminal 62 is reversed.

In the semiconductor module 1, when both the first semiconductor chip Q1 and the fourth semiconductor chip Q4 are turned on, a current flows from the first intermediate point terminal 61 to the second intermediate point terminal 62. Further, when both the third semiconductor chip Q3 and the second semiconductor chip Q2 are turned on, a current flows from the second intermediate point terminal 62 to the first intermediate point terminal 61.

Further, the outer lead portions of the first power source terminal 51 and the second power source terminals (one second power source terminal 52 and the other second power source terminal 53) and the outer lead portions of the first intermediate point terminal 61 and the second intermediate point terminal 62 are disposed on opposite sides of the semiconductor module 1. In this embodiment, the expression “on opposite sides of the semiconductor module 1” means an upper side of the semiconductor module 1 illustrated in the drawing and a lower side of the semiconductor module 1 illustrated in the drawing.

Outer lead portions of the first control-use terminal T11 and the third control-use terminal T13, and outer lead portions of the first power source terminal 51, one second power source terminal 52 and the other second power source terminal 53 are disposed on the same sides of the semiconductor module 1. Further, outer lead portions of the second control-use terminal T12 and the fourth control-use terminal T14, and outer lead portions of the first intermediate point terminal 61 and the second intermediate point terminal 62 are disposed on the same side of the semiconductor module 1.

Further, outer lead portions of the first detection-use terminal T21 and the third detection-use terminal T23, and outer lead portions of the first power source terminal 51, one second power source terminal 52 and the other second power source terminal 53 are disposed on the same side of the semiconductor module 1. Further, outer lead portions of the second detection-use terminal T22 and the fourth detection-use terminal T24, and outer lead portions of the first intermediate point terminal 61 and the second intermediate point terminal 62 are disposed on the same side of the semiconductor module 1.

Hereinafter, advantageous effects of the semiconductor module 1 according to the embodiment 1 are described.

In the semiconductor module 1 according to the embodiment 1, a width of at least one terminal (the first power source terminal 51, the first intermediate point terminal 61 or the second intermediate point terminal 62) out of the plurality of terminals is set so as to exhibit a desired inductance and, at the same time, the outer lead portion has the distal end branched structure 51B, 61B, 62B, where the distal end of the terminal of the outer lead portion is branched in plurals. With such a configuration, according to the semiconductor module 1 of the embodiment 1, with respect to at least one terminal out of the plurality of terminals, even when the terminal width from the inner lead portion to the outer lead portion is increased to a terminal width at which a parasitic inductance is not largely increased, the increase of the width of the distal end of the terminal is suppressed by the distal end branched structure 51B, 61B, 62B and hence, a heat capacity of a mounting portion is reduced whereby lowering of difficulty of mounting can be realized. Accordingly, the semiconductor module 1 according to the embodiment 1 becomes a semiconductor module that can also realize lowering of difficulty of mounting while realizing the reduction of a parasitic inductance.

Further, in the semiconductor module 1 according to the embodiment 1, at least one terminal (first power source terminal 51, first intermediate point terminal 61 and second intermediate point terminal 62) out of the plurality of terminals has the distal end branched structure 51B, 61B, 62B outside the mold resin. With such a configuration, according to the semiconductor module 1 of the embodiment, in a state where a portion that can secure the sufficient terminal width is increased as much as possible, lowering of difficulty of mounting can be also realized.

Further, in the semiconductor module 1 according to the embodiment 1, the semiconductor module 1 includes four semiconductor chips (semiconductor chips Q1 to Q4) as the plurality of semiconductor chips. Further, the semiconductor module 1 includes the first power source terminal 51, the second power source terminals (one second power source terminal 52 and the other second power source terminal 53), the first intermediate point terminal 61 and the second intermediate point terminal 62 as the plurality of terminals. Further, in the semiconductor module 1 according to the embodiment 1, both the outer lead portions of the first intermediate point terminal 61 and the second intermediate point terminal 62 have the distal end branched structure 61B, 62B. With such a configuration, according to the semiconductor module 1 of the embodiment 1, by also allowing the first intermediate point terminal 61 and the second intermediate point terminal 62 to have the distal end branched structure 61B, 62B, lowering of difficulty of mounting can be also realized while realizing the further reduction of a parasitic inductance.

Further, in the semiconductor module 1 according to the embodiment 1, the semiconductor module 1 includes one second power source terminal 52 and the other second power source terminal 53 as the second power source terminals. Further, in the semiconductor module 1 according to the embodiment 1, out of the first power source terminal 51, one second power source terminal 52 and the other second power source terminal 53, only the outer lead portion of the first power source terminal 51 has the distal end branched structure 51B. With such a configuration, in the semiconductor module 1 according to the embodiment 1, by setting a terminal width of the first power source terminal 51 from the inner lead portion to the outer lead portion larger than a terminal width of two existing second power source terminals and, at the same time, by allowing the first power source terminal 51 to have the distal end branched structure 51B, it is also possible to realize lowering of difficulty of mounting while realizing the further reduction of a parasitic inductance.

Further, in the semiconductor module 1 according to the embodiment 1, in each of the plurality of terminals (first power source terminal 51, one second power source terminal 52, the other second power source terminal 53, the first intermediate point terminal 61 and the second intermediate point terminal 62), the maximum width of the inner lead portion is set wider than the maximum width of the outer lead portion. With such a configuration, according to the semiconductor module 1 of the embodiment 1, the further reduction of a parasitic inductance can be realized.

Further, in the semiconductor module 1 according to the embodiment 1, the distal end branched structure 51B, 61B, 62B is the distal end bifurcated structure where the distal end of the terminal is branched in two, wherein a maximum width of the inner lead portion is two time or more as large as a terminal width of a portion that is branched at the distal end bifurcated structure. With such a configuration, according to the semiconductor module 1 of the embodiment 1, the width of the inner lead portion is set larger than a spaced-apert distance of the distal end bifurcated structure and hence, the further reduction of a parasitic inductance can be realized.

Further, in the semiconductor module 1, the respective constitutional elements are arranged in symmetry with respect to the center line C, or are formed in symmetry with respect to the center line C. With such a configuration, according to the semiconductor module 1 of the embodiment 1, it is possible to make a length of a current path when both the first semiconductor chip Q1 and the fourth semiconductor chip Q4 are turned on and a length of a current path when both the third semiconductor chip Q3 and the second semiconductor chip Q2 are turned on agree with each other. As a result, it is possible to make a parasitic inductance generated when both the first semiconductor chip Q1 and the fourth semiconductor chip Q4 are turned on and a parasitic inductance generated when both the third semiconductor chip Q3 and the second semiconductor chip Q2 are turned on agree with each other. As a result, according to the semiconductor module 1, it is possible to acquire an advantageous effect that the reduction of a parasitic inductance can be also realized from this point of view.

Further, in the semiconductor module 1 according to the embodiment 1, at the time of using the semiconductor module 1, a current flows in opposite directions between the first power source terminal 51 and one second power source terminal 52 and the other second power source terminal 53 and, at the same time, between the first intermediate point terminal 61 and the second intermediate point terminal 62. Further, the first intermediate point terminal 61 and the second intermediate point terminal 62 are disposed adjacently to each other on one side of the semiconductor module 1. Further, the first power source terminal 51, one second power source terminal 52 and the other power source terminal 53 are disposed on the other side of the semiconductor module 1, and the first power source terminal 51 is disposed in a space above the fifth pattern 50 in a non-contact state. With such a configuration, in the semiconductor module 1 according to the embodiment 1, a current flows in opposite directions between the first power source terminal 51 and the fifth wiring pattern 50 and, at the same time, a current flows in opposite directions between the first intermediate point terminal 61 and the second intermediate point terminal 62. As a result, according to the semiconductor module 1, it is possible to make a magnetic field generated in the first power source terminal 51 and the fifth wiring pattern 50 and a magnetic field generated in the first intermediate point terminal 61 and the second intermediate point terminal 62 cancel each other whereby it is possible to acquire an advantageous effect that the reduction of a parasitic inductance can be realized.

As has been described above, according to the semiconductor module 1 of the embodiment 1, it is possible to realize the lowering of difficulty in mounting while realizing the reduction of a parasitic inductance. Inventors of the present invention carried out a simulation for verifying the advantageous effects relating particularly to a parasitic inductance. Hereinafter, the result of the simulation is described.

In the simulation, a semiconductor module 1A was estimated for comparison with the semiconductor module 1 according to the embodiment 1 (see FIG. 3). The semiconductor module 1A has substantially the same constitutional elements as the semiconductor module 1 according to the embodiment 1. In FIG. 3, the constitutional elements substantially identical with the corresponding constitutional elements of the semiconductor module 1 are indicated by substantially the same symbols.

The semiconductor module 1A includes, as constitutional elements that correspond to the first power source terminal, one second power source terminal, the other second power source terminal, the first intermediate point terminal and the second intermediate point terminal of the semiconductor module 1 according to the embodiment 1, a first power source terminal 851, one second power source terminal 852, the other second power source terminal 853, a first intermediate point terminal 861 and a second intermediate point terminal 862. To compare with the first power source terminal 51, in the first power source terminal 851, a width of an inner lead portion and a width of an outer lead portion are narrow. The same goes for one second electrode terminal 852, the other second electrode terminal 853, the first intermediate point terminal 861, and the second intermediate point terminal 862. Further, none of the first power source terminal 851, the first intermediate point terminal 861 and the second intermediate point terminal 862 have a distal end branched structure.

The configuration of a bridge circuit of the semiconductor module 1A is substantially equal to the configuration of the bridge circuit of the semiconductor module 1 according to the embodiment 1. That is, in the bridge circuit, the first semiconductor chip Q1 and the third semiconductor chip Q3 are disposed on a high side, and the second semiconductor chip Q2 and the fourth semiconductor chip Q4 are disposed on a low side. Also in the semiconductor module 1A, both the first semiconductor chip Q1 and the fourth semiconductor chip Q4 are turned on, and both the third semiconductor chip Q3 and the second semiconductor chip Q2 are turned on.

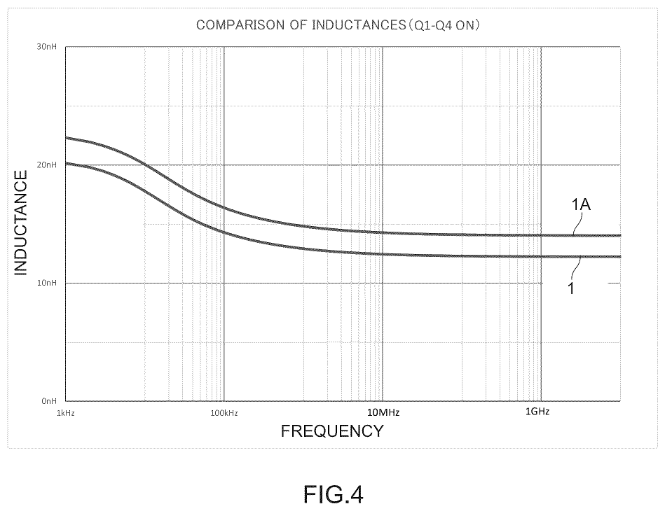

A result obtained by comparing a parasitic inductance generated in the semiconductor module 1A according to the embodiment 1 and a parasitic inductance generated in the semiconductor module 1A according to the embodiment 1A is described (see FIG. 4). In this simulation, a parasitic inductance generated in a current path when the first semiconductor chip Q1 and the fourth semiconductor module Q4 are turned on with a frequency of an on/off operation of the bridge circuit set within a range of 1 kHz to 1 GHz or more was measured.

In the semiconductor module 1A, parasitic inductances that were generated in a current path when both the first semiconductor chip Q1 and the fourth semiconductor chip Q4 were turned on were 22.30 nH at 1 kHz, 16.38 nH at 100 kHz, and 14.09 nH at 100 MHZ.

On the other hand, in the semiconductor module 1, parasitic inductances that were generated in a current path when both the first semiconductor chip Q1 and the fourth semiconductor chip Q4 were turned on were 20.15 nH at 1 KHz, 14.28 nH at 100 kHz, and 12.29 nH at 100 MHz.

Both in the semiconductor module 1 according to the embodiment 1 and in the semiconductor module 1A, the respective constitutional elements are disposed in symmetry with respect to the center line C, or are formed in symmetry with respect to the center line C. Accordingly, it is also considered that, when both of the third semiconductor chip Q3 and the second semiconductor chip Q2 are turned on, the substantially same advantageous effects can be also acquired.

From the above-mentioned result, it was confirmed that the semiconductor module 1 according to the embodiment 1 can reduce a parasitic conductance compared to the semiconductor module 1A.

### Embodiment 2

The semiconductor module 2 according to the embodiment 2 basically has substantially the same configuration as the semiconductor module 1 according to the embodiment 1. However, the semiconductor module 2 according to the embodiment 2 differs from the semiconductor module 1 according to the embodiment 1 with respect to the configurations of a first power source terminal, a second power source terminal, a first intermediate point terminal, a second intermediate point terminal, and wiring patterns. The semiconductor module 2 includes, as illustrated in FIG. 5, the plurality of semiconductor chips (semiconductor chips Q1 to Q4), and the first power source terminal 51a, the second power source terminal 52a, the first intermediate point terminal 61a and the second intermediate point terminal 62a all of which are disposed in the mold resin M. Further, in the semiconductor module 2, a bridge is circuit is formed where the first semiconductor chip Q1 and third semiconductor chip Q3 are disposed on a high side and the second semiconductor chip Q2 and the fourth semiconductor chip Q4 are disposed on a low side. Hereinafter, the semiconductor module 2 is described by focusing on the difference between the semiconductor module 2 and the semiconductor module 1 according to the embodiment 1.

The semiconductor module 2 includes one second power source terminal 52a. The second power source terminal 52a is configured such that an inner lead portion is positioned inside the mold resin M, and respective outer lead portions are positioned outside the mold resin M.

The semiconductor module 2 includes: besides the above-mentioned constitutional elements, first to fourth wiring patterns 10a to 40a, a substrate 70, first to fourth connecting members 81 to 84, first to fourth control-use connecting members (symbols not illustrated in the drawings), first to fourth detection-use connecting members (symbols not illustrated in the drawings), first to fourth control-use wiring patterns 111 to 114, first to fourth detection-use wiring patterns 121 to 124, first to fourth control-use terminals T11 to T14, and first to fourth detection-use terminals T21 to T24. The semiconductor module 2 may further include constitutional elements other than the above-mentioned constitutional elements.

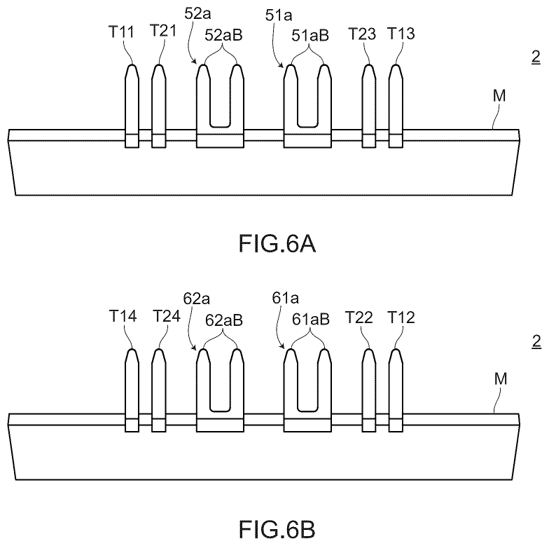

In the semiconductor module 2, outer lead portions formed on terminals of both the first power source terminal 51a and the second power source terminal 52a each have a distal end branched structure 51aB, 52aB where distal end of the terminal is branched in plurals (see FIG. 6A).

In the first power source terminal 51a and the second power source terminal 52a, a maximum width of the inner lead portion is set larger than a maximum width of the outer lead portion. Further, the terminals of the first power source terminal 51a and the second power source terminal 52a each have the distal end branched structure 51aB, 52aB outside the mold resin M.

Both the outer lead portion of the first intermediate point terminal 61a and the outer lead portion of the second intermediate point terminal 62a each have a distal end branched structure 61aB, 62aB (see FIG. 6B). Also in the first intermediate point terminal 61a and the second intermediate point terminal 62a, a maximum width of the inner lead portion is set larger than a maximum width of the outer lead portion. Further, the first intermediate point terminal 61a and the second intermediate point terminal 62a each have the distal end branched structure 61aB, 62aB outside the mold resin M.

In the semiconductor module 2, the distal end branched structure 51aB, 52aB, 61aB, 62aB in the first power source terminal 51a, the second power source terminal 52a, the first intermediate point terminal 61a, and the second intermediate point terminal 62a each have a distal end bifurcated structure where the distal end of the terminal is branched in two. A maximum width of the inner lead portion of each terminal is two times or more as large as a terminal width of a portion branched in the distal end bifurcated structure.

The first power source terminal 51a is connected to the first wiring pattern 10a. Further, assuming one side of a plurality of sides of the first wiring pattern 10a as a first side 11, a recessed portion 12 having a recessed shape when the first wiring pattern 10a is viewed in a plan view is formed on the first side 11 within a predetermined range of the first side 11. In this embodiment, with respect to the first wiring pattern 10a, in FIG. 5, the side that is disposed on an upper side in the drawing out of sides of the first wiring pattern 10a that extends in the lateral direction in the drawing is assumed as the first side 11.

The expression “recessed portion 12” does not indicate a recessed portion that is indented in a thickness direction of the substrate 70. That is, as illustrated within a region surrounded by a broken like frame Z in FIG. 5, the expression “recessed portion 12” indicates a recessed portion indented in a recessed shape in a downward direction on a paper surface on a plane of a substrate 70 when the first wiring pattern 10a is viewed in a plan view.

Further, the first semiconductor chip Q1 and the third semiconductor chip Q3 are mounted on the first wiring pattern 10a. In such a configuration, the first semiconductor chip Q1 and the third semiconductor chip Q3 are mounted at positions that sandwich the recessed portion 12. Assume that the position at which the recessed portion 12 is formed is in the vicinity of the substantially center of the first wiring pattern 10a in the lateral direction.

Subsequently, the second wiring pattern 20a is described. The second power source terminal 52a is connected to the second wiring pattern 20a. As viewed in a plan view, three sides of the second wiring pattern 20a is surrounded by the recessed portion 12 of the first wiring 10a as viewed in a plan view.

Subsequently, the third wiring pattern 30a and the fourth wiring pattern 40a are described. The third wiring pattern 30a and the fourth wiring pattern 40a are disposed side by side in the lateral direction along the first side 11 of the wiring pattern 10a.

The third wiring pattern 30a is disposed adjacently to the first wiring pattern 10a and the second wiring pattern 20a. The second semiconductor chip Q2 is mounted on the third wiring pattern 30a, and the first intermediate point terminal 61a is connected to the third wiring pattern 30a.

The fourth wiring pattern 40a is disposed adjacently to the first wiring pattern 10a and the second wiring pattern 20a. The fourth semiconductor chip Q4 is mounted on the fourth wiring pattern 40a, and the second intermediate point terminal 62a is connected to the fourth wiring pattern 40a.

The expression “adjacently to” in this specification means a state where, when two constitutional elements of the same kind are focused, a constitutional element which is of the same kind as the above-mentioned two constitutional elements is not disposed there between.

The wiring patterns 10a to 40a have such arrangement and hence, the second wiring pattern 20a is surrounded by the first wiring pattern 10a, the third wiring pattern 30a and the fourth wiring pattern 40a, and is positioned in the vicinity of the center of the substrate 70.

Next, the semiconductor chips Q1 to Q4 are described.

A first source electrode S1 of the first semiconductor chip Q1 is connected to the third wiring pattern 30a via a first connecting member 81 made of aluminum wire or the like. Further, a first drain electrode of the first semiconductor chip Q1 is connected to the first wiring pattern 10a.

A second source electrode S2 of the second semiconductor chip Q2 is connected to the second wiring pattern 20a via a second connecting member 82 made of aluminum wire or the like. Further, a second drain electrode of the second semiconductor chip Q2 is connected to the third wiring pattern 30a.

A third source electrode S3 of the third semiconductor chip Q3 is connected to the fourth wiring pattern 40a via a third connecting member 83 made of aluminum wire or the like. Further, a third drain electrode of the third semiconductor chip Q3 is connected to the first wiring pattern 10a.

A fourth source electrode S4 of the fourth semiconductor chip Q4 is connected to the second wiring pattern 20a via a fourth connecting member 84 made of aluminum wire or the like. Further, a fourth drain electrode of the fourth semiconductor chip Q4 is connected to the fourth wiring pattern 40a.

The first to fourth control-use terminals T11 to T14 and the first to fourth detection-use terminal T21 to T24 are disposed outside a region surrounded by the first power source terminal 51a and the second power source terminal 52a and outside a region surrounded by the first intermediate point terminal 61a and the second intermediate point terminal 62a. The connection relationships of the first to fourth control-use terminals T11 to T14, the first to fourth detection-use terminals T21 to T24, the first to fourth control wiring patterns 111 to 114, the first to fourth detection wiring patterns 121 to 124 and the semiconductor chips Q1 to Q4 are substantially equal to the case described in the embodiment 1 and hence, the description of such connection relationships is omitted.

Next, the first and the second power source terminals 51a, 52a and the first and the second intermediate point terminals 61a, 62a in the semiconductor module 2 are described. The first power source terminal 51a and the second power source terminal 52a are terminals for supplying electricity to the bridge circuit. When such a configuration is viewed from a point of the flow of a current, assume that the first power source terminal 51a forms an input side of the current and the second power source terminal 52a forms an output side of the current.

The first power source terminal 51a is connected to the first wiring pattern 10a. The second power source terminal 52a is connected to the second wiring pattern 20a in a straddling manner over the first wiring pattern 10a in a non-contact state. These first power source terminal 51a and the second power source terminal 52a are disposed adjacently to each other. Further, a decoupling capacitor 90 is disposed in the vicinity of the first power source terminal 51a and the second power source terminal 52a. One end of the decoupling capacitor 90 is connected to the first wiring pattern 10a, and the other end of the decoupling capacitor 90 is connected to the second wiring pattern 20a.

On the other hand, the first intermediate point terminal 61a and the second intermediate point terminal 62a are terminals to which a load not illustrated in the drawing is connected. The first intermediate point terminal 61a is connected to the third wiring pattern 30a, and the second intermediate point terminal 62a is connected to the fourth wiring pattern 40a. These first intermediate point terminal 61a and second intermediate point terminal 62a are disposed adjacently to each other. The direction of a current that flows between the first intermediate point terminal 61a and the second intermediate point terminal 62a becomes opposite between a case where both the first semiconductor chip Q1 and the fourth semiconductor chop Q4 are turned on and a case where both the third semiconductor chip Q3 and the second semiconductor chip Q2 are turned on.

In the semiconductor module 2, when both the first semiconductor chip Q1 and the fourth semiconductor chip Q4 are turned on, a current flows from the first intermediate point terminal 61a to the second intermediate point terminal 62a. On the other hand, when both the third semiconductor chip Q3 and the second semiconductor chip Q2 are turned on, a current flows from the second intermediate point terminal 62a to the first intermediate point terminal 61a.

Further, as illustrated in FIG. 5, the outer lead portion of the first power source terminal 51a and the outer lead portion of the second power source terminal 52a are disposed on a side of the semiconductor module 2 opposite to a side of the semiconductor module 2 where the outer lead portion of the first intermediate point terminal 61a and the outer lead portion of the second intermediate point terminal 62a are disposed.

The outer lead portion of the first control-use terminal T11 and the outer lead portion of third control-use terminal T13 as well as the outer lead portion of the first power source terminal 51a and the outer lead portion of the second power source terminal 52a are disposed on the same side of the semiconductor module 2. On the other hand, the outer lead portion of the second control-use terminal T12 and the outer lead portion of the fourth control-use terminal T14 as well as the outer lead portion of the first intermediate point terminal 61a and the outer lead portion of the second intermediate point terminal 62a are disposed on the same side of the semiconductor module 2.

Further, the outer lead portion of the first detection-use terminal T21 and the outer lead portion of the third detection-use terminal T23 as well as the outer lead portion of the first power source terminal 51a and the outer lead portion of the second power source terminal 52a are disposed on the same side of the semiconductor module 2. Further, the outer lead portion of the second detection-use terminal T22 and the outer lead portion of the fourth detection-use terminal T24 as well as the outer lead portion of the first intermediate point terminal 61a and the outer lead portion of the second intermediate point terminal 62a are disposed on the same side of the semiconductor module 2.

In the semiconductor module 2, a current path when both the first semiconductor chip Q1 and the fourth semiconductor chip Q4 are turned on becomes as follows. That is, the current path is a path where a current flows from the first power source terminal 51a, passes the first semiconductor chip Q1 and reaches the first intermediate point terminal 61a, the current flows from the first intermediate point terminal 61a and passes the load not illustrated in the drawing and, thereafter, the current flows from the second intermediate point terminal 62a, passes the fourth semiconductor chip Q4 and reaches the second power source terminal 52a.

On the other hand, a current path when both the third semiconductor chip Q3 and the second semiconductor chip Q2 are turned on becomes as follows. That is, the current path is a path where a current flows from the first power source terminal 51a, passes the third semiconductor chip Q3 and reaches the second intermediate point terminal 62a, the current flows from the second intermediate point terminal 62a and passes the load not illustrated in the drawing and, thereafter, the current flows from the first intermediate point terminal 61a, passes the second semiconductor chip Q2 and reaches the second power source terminal 52a.

That is, with respect to the current path when both the first semiconductor chip Q1 and the fourth semiconductor chip Q4 are turned on, a current flows from the first power source terminal 51a and enters the first wiring pattern 10a, flows from the first drain electrode of the first semiconductor chip Q1 mounted on the first wiring pattern 10a, passes the first source electrode S1, passes the third wiring pattern 30a via the first connecting member 81 that connects the first source electrode S1 and the third wiring pattern 30a, and flows into the first intermediate point terminal 61a. Thereafter, the current flows from the second intermediate point terminal 62a to the fourth wiring pattern 40a via the load not illustrated in the drawing, flows from the fourth drain electrode of the fourth semiconductor chip Q4 mounted on the fourth wiring pattern 40a, passes the fourth source electrode S4, passes the second wiring pattern 20a via the fourth connecting member 84 that connects the fourth source electro S4 and the second wiring pattern 20a, and flows into the second power source terminal 52a.

On the other hand, with respect to the current path when both the third semiconductor chip Q3 and the second semiconductor chip Q2 are turned on, a current flows from the first power source terminal 51a and enters the first wiring pattern 10a, flows from the third drain electrode of the third semiconductor chip Q3 mounted on the first wiring pattern 10a, passes the third source electrode S3, passes the fourth wiring pattern 40a via the third connecting member 83 that connects the third source electrode S3 and the fourth wiring pattern 40a, and flows into the second intermediate point terminal 62a. Thereafter, the current flows from the first intermediate point terminal 61a to the third wiring pattern 30a via the load not illustrated in the drawing, flows from the second drain electrode of the second semiconductor chip Q2 mounted on the third wiring pattern 30a, passes the second source electrode S2, passes the second wiring pattern 20a via the second connecting member 82 that connects the second source electrode S2 and the second wiring pattern 20a, and flows into the second power source terminal 52a.

In this manner, at the time of using the semiconductor module 2, currents flow in opposite directions between the first power source terminal 51a and the second power source terminal 52a and, at the same time, currents flow in opposite directions between the first intermediate point terminal 61a and the second intermediate point terminal 62a.

Further, the current path when both the first semiconductor chip Q1 and the fourth semiconductor chip Q4 are turned on and the current path when both the third semiconductor chip Q3 and the second semiconductor chip Q2 are turned on, are formed on the second wiring pattern 20a and the surrounding of the second wiring pattern 20a. Such current paths are formed due to the arrangement of the wiring patterns 10a to 40a, the arrangement of the semiconductor chips Q1 to Q4, and the arrangement of the first and second power source terminals 51a, 52a and the first and second intermediate point terminals 61a, 62a.

Hereinafter, the advantageous effects of the semiconductor module 2 according to the embodiment 2 are described.

The semiconductor module 2 according to the embodiment 2 differs from the semiconductor module 1 according to the embodiment 1 with respect to the configurations of the first power source terminal, the second power source terminal, the first intermediate point terminal, the second intermediate point terminal, and the wiring patterns. However, in the semiconductor module 2 according to the embodiment 2, a width of at least one terminal (the first power source terminal 51a, the second power source terminal 52a, the first intermediate point terminal 61a or the second intermediate point terminal 62a) out of the plurality of terminals is set so as to exhibit a desired inductance and, at the same time, outer lead portion has the distal end branched structure 51aB, 52aB, 61aB, 62aB, where the distal end of the terminal is branched in plurals. With such a configuration, according to the semiconductor module 2 of the embodiment 2 in the same manner as the semiconductor module 1 according to the embodiment 1, with respect to at least one terminal out of the plurality of terminals, even when the terminal width from the inner lead portion to the outer lead portion is increased to a terminal width at which a parasitic inductance is not largely increased, the increase of the width of the distal end of the terminal is suppressed by the distal end branched structure 51aB, 52aB, 61aB, 62aB and hence, a heat capacity of a mounting portion is reduced whereby lowering of difficulty of mounting can be realized. Accordingly, the semiconductor module 2 according to the embodiment 2 becomes a semiconductor module that can also realize lowering of difficulty of mounting while realizing the reduction of a parasitic inductance.

Further, in the semiconductor module 2 according to the embodiment 2, both the outer lead portion of the first power source terminal 51a and the outer lead portion of the second power source terminal 52a each have the distal end branched structure 51aB, 52aB. With such a configuration, in the semiconductor module 2 according to the embodiment 2, also with respect to both the first power source terminal 51a and the second power source terminal 52a, lowering of difficulty in mounting can be realized while realizing the reduction of a parasitic inductance.

Further, in the semiconductor module 2 according to the embodiment 2, the first power source terminal 51a and the second power source terminal 52a are disposed adjacently to each other, and the first intermediate point terminal 61a and the second intermediate point terminal 62a are disposed adjacently to each other. Further, in the semiconductor module 2, the direction of a current that flows in the first power source terminal 51a and the direction of a current that flows in the second power source terminal 52a become directions opposite to each other, and the direction of a current that flows in the first intermediate point terminal 61a and the direction of a current that flows in the second intermediate point terminal 62a become opposite to each other. In this manner, by arranging the terminals having different directions in the flow of a current adjacently to each other, generated magnetic fields can be cancelled to each other and hence, it is possible to acquire an advantageous effect that the reduction of a parasitic inductance can be realized.

Further, the semiconductor module 2 according to the embodiment 2 also acquires advantageous effects corresponding to the advantageous effects out of the advantageous effects that the semiconductor module 1 according to the embodiment 1 possesses.

### Embodiment 3

A semiconductor module 3 according to the embodiment 3 includes: as illustrated in FIG. 7, a plurality of semiconductor chips and a plurality of terminals that are disposed inside a mold resin M. To further describe the configuration in detail, the semiconductor module 3 includes two semiconductor chips (semiconductor chips Q1, Q2) as the plurality of semiconductor chips. Further, the semiconductor module 3 includes, as a plurality of terminals, a first power source terminal 51b, a second power source terminal 52b and an intermediate point terminal 61b. In this manner, the semiconductor module 3 is a semiconductor module where a half bridge circuit is formed.

In the first power source terminal 51b, the second power source terminal 52b and the intermediate point terminal 61b, an inner lead portion of each terminal is positioned inside the mold resin M, and an outer lead portion of each terminal is disposed outside the mold resin M.

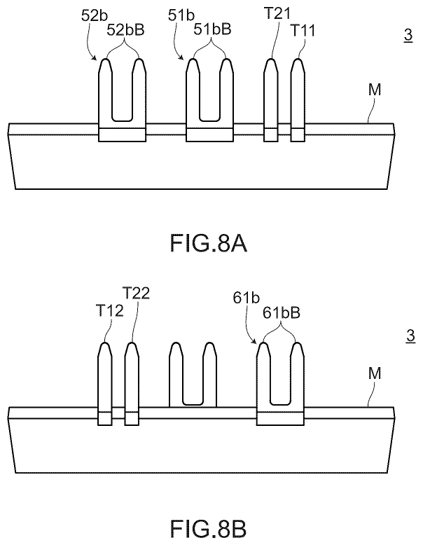

In the first power source terminal 51b and the second power source terminal 52b, the outer lead portion has a distal end branched structure 51bB, 52bB where a distal end of the terminal is branched in plural (see FIG. 8A). Further, the first power source terminal 51b and the second power source terminal 52b have the distal end branched structure 51bB, 52bB outside the mold resin M.

The outer lead portion of the intermediate point terminal 61b has a distal end branched structure 61bB (see FIG. 8B). Further, the intermediate point terminal 61b has the distal end branched structure 61bB outside the mold resin M.

Further, the semiconductor module 3 includes, besides the above-mentioned constitutional elements, first to third wiring pattern 10b to 30b, a substrate 70, first and second connecting members 81, 82, first and second control-use connecting members (symbols not illustrated in the drawing), first and second detection-use connecting members (symbols not illustrate in the drawing), first and second control-use wiring patterns 111, 112, first and second detection-use wiring patterns 121, 122, first and second control-use terminals T11, T12, and first and second detection-use terminals T21, T22. The semiconductor module 3 may further include constitutional elements other than above-mentioned constitutional elements.

A first source electrode S1 of the first semiconductor chip Q1 is connected to the third wiring pattern 30b via the first connecting member 81 made of an aluminum wire or the like. Further, a first drain electrode of the first semiconductor chip Q1 is connected to the first wiring pattern 10b.

A second source electrode S2 of the second semiconductor chip Q2 is connected to the second wiring pattern 20b via the second connecting member 82 made of an aluminum wire or the like. Further, a second drain electrode of the second semiconductor chip Q2 is connected to the third wiring pattern 30a.

The first power source terminal 51b is connected to the first wiring pattern 10b. The second power source terminal 52b is connected to the second wiring pattern 20b. These first power source terminal 51b and the second power source terminal 52b are disposed adjacently to each other.

On the other hand, the intermediate point terminal 61b is a terminal to which a load not illustrated in the drawing is connected. The intermediate point terminal 61b is connected to the third wiring pattern 30b.

Hereinafter, the advantageous effects of the semiconductor module 3 according to the embodiment 3 is described.

The semiconductor module 3 according to the embodiment 3 differs from the semiconductor module 1 according to the embodiment 1 with respect to the overall configuration. However, in the semiconductor module 3 according to the embodiment 3, a width of at least one terminal (the first power source terminal 51b, the second power source terminal 52b and the intermediate point terminal 61b) out of the plurality of terminals is set so as to have a desired inductance. Further, the outer lead portion has the distal end branched structure 51bB, 52bB, 61bB where a distal end of the terminal is branched in plurals. With such a configuration, in the semiconductor module 3 according to the embodiment 3, in the same manner as the semiconductor module 1 according to the embodiment 1, with respect to at least one terminal out of the plurality of terminals, even when the terminal width from the inner lead portion to the outer lead portion is increased to a terminal width at which a parasitic inductance is not largely increased, the increase of the width of the distal end of the terminal is suppressed by the distal end branched structure 51bB, 52bB, 61bB and hence, a heat capacity of a mounting portion is reduced whereby lowering of difficulty of mounting can be realized. Accordingly, the semiconductor module 3 according to the embodiment 3 becomes a semiconductor module that can also realize lowering of difficulty of mounting while realizing the reduction of a parasitic inductance.

Further, the semiconductor module 3 according to the embodiment 3 includes two semiconductor chips (semiconductor chips Q1, Q2) as the plurality of semiconductor chips, and the first power source terminal 51b, the second power source terminal 52b and the intermediate point terminal 61b as the plurality of terminals. Further, the outer lead portion of the intermediate point terminal 61b has the distal end branched structure 61bB. With such a configuration, according to the semiconductor module 3 according to the embodiment 3, the intermediate point terminal 61b also has the distal end branched structure 61bB and hence, it is possible to realize the lowering of difficulty in mounting while realizing the further reduction of a parasitic inductance.

Further, the semiconductor module 3 according to the embodiment 3 also acquires advantageous effects corresponding to the advantageous effects out of the advantageous effects that the semiconductor module 1 according to the embodiment 1 possesses.

The present invention is not limited to the above-mentioned respective embodiments, and can be carried out in the form of various modifications without departing from the gist of the present invention. For example, the following modifications are conceivable.

The shapes, the numbers, sizes, the positions and the like of the constitutional elements in the semiconductor module according to the present invention are not limited to those described in the respective drawings, and can be suitably changed provided that the technical features of the present invention are not impaired.

(2) The semiconductor chips Q1 to Q4 are not limited to the MOSFET. The semiconductor chips Q1 to Q4 may be formed of other semiconductor chips such as an insulated gate bipolar transistor (IGBT).

(3) In the above-mentioned respective embodiments, the semiconductor modules each include four or two semiconductor chips. However, the present invention is not limited to such semiconductor modules. The present invention is also applicable to semiconductor modules where the number of the semiconductor chips is neither four nor two.

(4) In the above-mentioned respective embodiments, the description has been made with respect to the case where the distal end branched structure of each terminal has the distal end bifurcated structure in which the distal end of the terminal is branched in two. However, the present invention is not limited to such a configuration. The distal end branched structure may be a structure where the distal end of the terminal is branched in three or more.

1. A semiconductor module comprising:
a plurality of semiconductor chips arranged inside a mold resin; and
a plurality of terminals each having an inner lead portion that is positioned inside the mold resin and having an outer lead portion that is positioned outside the mold resin, wherein
a width of at least one terminal out of the plurality of terminals is set such that the terminal has a desired inductance, and
the terminal has a distal end branched structure where a distal end of the terminal at the outer lead portion is branched in plurals.

2. The semiconductor module according to claim 1, wherein
the at least one terminal out of the plurality of terminals has the distal end branched structure outside the mold resin.

3. The semiconductor module according to claim 1, wherein
the semiconductor module is a semiconductor module that comprises four semiconductor chips as the plurality of semiconductor chips and comprises a first power source terminal, a second power source terminal, a first intermediate point terminal, and a second intermediate point terminal as the plurality of terminals thus forming a bridge circuit, and
both the outer lead portion at the first intermediate point terminal and the outer lead portion at the second intermediate point terminal have the distal end branched structure.

4. The semiconductor module according to claim 3, wherein
the semiconductor module includes one second power source terminal and an other second power source terminal as the second power source terminal, wherein
out of the first power source terminal, the one second power source terminal and the other second power source terminal, only the outer lead portion of the first power source terminal has the distal end branched structure.

5. The semiconductor module according to claim 3, wherein
both the outer lead portion of the first power source terminal and the outer lead portion of the second power source terminal have the distal end branched structure.

6. The semiconductor module according to claim 1, wherein
the semiconductor module is a semiconductor module that includes two semiconductor chips as the plurality of semiconductor chips, includes a first power source terminal, a second power source terminal and an intermediate point terminal as the plurality of terminals thus forming a half bridge circuit, and
the outer lead portion at the intermediate point terminal has the distal end branch structure.

7. The semiconductor module according to claim 1, wherein
in the plurality of terminals, a maximum width of the inner lead portion is set larger than a maximum width of the outer lead portion.

8. The semiconductor module according to claim 1, wherein
the distal end branched structure is a distal end bifurcated structure where the distal end of the terminal is branched in two, and
a maximum width of the inner lead portion is more than twice as large as a terminal width of a branched portion of the distal end bifurcated structure.
